(19) United States
(12) Patent Application Publication
(10) Pub. No.: US 2009/0158752 A1
(43) Pub. Date: Jun. 25, 2009

(54) VARIABLE POWER CRYOGENIC REFRIGERATOR

(75) Inventors: Nicholas John CLAYTON, Oxford (GB); David Gubbins, Abingdon (GB); Trevor Bryan Husband, Banbury (GB); Philip Alan Charles Walton, Witney (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Magnet Technology Ltd., Witney (GB)

(21) Appl. No.: 12/337,137

(22) Filed: Dec. 17, 2008

(30) Foreign Application Priority Data
Dec. 19, 2007 (GB) 0724713.3

(51) Int. Cl. F25B 9/14; F25B 19/00; G01R 33/3815

(52) U.S. Cl. 62/6; 62/51.1; 324/318

(57) ABSTRACT

A compressor (1) including a compressor mechanism; an input line (12) for providing gas to the compressor; and an output line (14) for providing compressed gas from the compressor. The compressor may supply gas at a first pressure or at a second pressure, by variation of the charge pressure within a gas circuit. A buffer volume and arrangement of valves, contained within the compressor, facilitate the change in static charge pressure. The electrical power drawn by the compressor is reduced when the charge pressure is reduced. Changing the charge pressure in the compressor also varies the cooling power delivered by the refrigerator. Therefore, this variable charge compressor can be used to reduce the electrical power drawn by an MRI system when it is in standby, and the full refrigeration capability is not required. Also, this has the effect of reducing wear and increasing the life of certain components within the refrigerator and compressor.

The present invention relates to cryogenic refrigerators, particularly such refrigerators operated by a compressed gas such as helium gas.

Helium gas compressors find use in supplying refrigerators for cooling superconducting magnets such as used in magnetic resonance imaging (MRI) systems. The refrigerators, supplied by the helium compressors, serve to maintain the superconducting magnets at a cryogenic temperature sufficiently cold to ensure that the coils of wire used to produce a magnetic field are superconducting. When the magnets are in use, for example during an imaging sequence, an increased amount of heat is generated, as compared to when the magnet is in a standby state, not performing any imaging.

In order to ensure that sufficient refrigeration power is available to maintain the superconducting magnet cooled during an imaging sequence, current practice is to operate the refrigeration system, and so correspondingly also the compressor, constantly at maximum power regardless of the refrigeration power actually required at any particular time. The electrical power consumption required to provide this constant maximum refrigeration power may be considered excessive, for example 9 kW. With the increasing awareness of environmental issues and increasing power costs, it is required to reduce the mean power consumption of such refrigeration systems.

Much of the electrical power consumed in operating such a refrigeration system is consumed by the helium compressor. The present invention seeks to reduce the mean power consumption of a gas compressor, thereby reducing the cost of ownership, and reducing the environmental impact of the use of the compressor.

Furthermore, wear of the component parts of the compressor would be reduced if the mean electrical power consumption of the compressor could be reduced. The present invention therefore also seeks to reduce the rate of wear of component parts of a gas compressor, thereby reducing the cost of ownership, and reducing the environmental impact of the ownership of a compressor, for example by reducing the need for replacement of parts, and increasing the useful life of the compressor.

The present invention accordingly provides apparatus and methods as set out in the appended claims.

The above, and further, objects, advantages and characteristics of the present invention will become more apparent from consideration of the following description of certain embodiments, given by way of examples only, wherein:

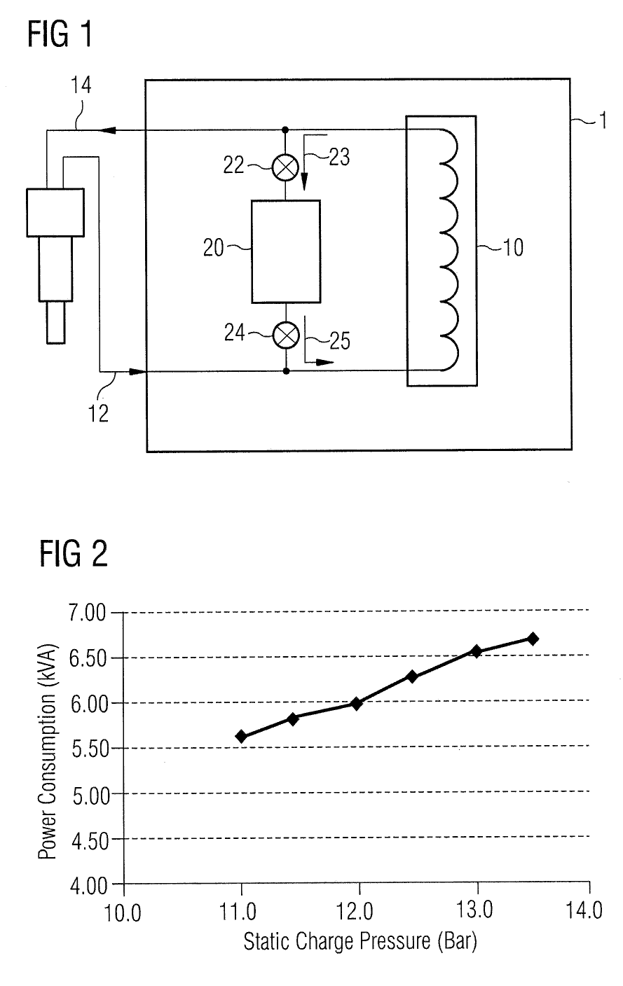

FIG. 1 schematically illustrates an example of a variable charge compressor connected to a cryogenic refrigerator in an arrangement according to an embodiment of the present invention;

FIG. 2 shows a graph of static charge pressure related to power consumption in a gas compressor suitable for use in the present invention;

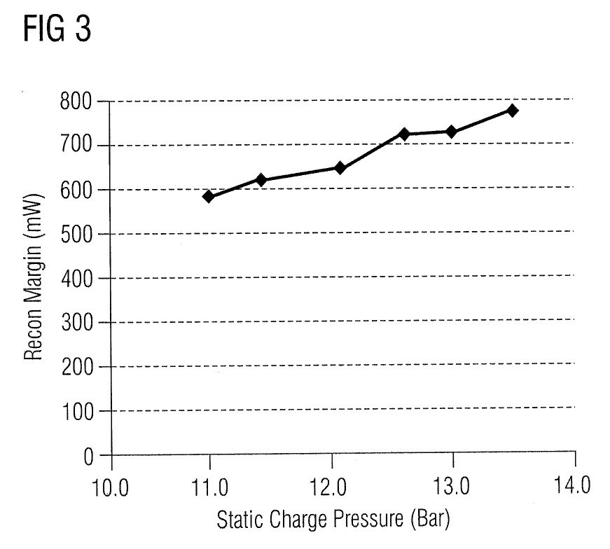

FIG. 3 shows a graph of the relationship between static charge pressure and recondensing margin of a cooled MRI magnet system comprising an arrangement according to an embodiment of the present invention; and

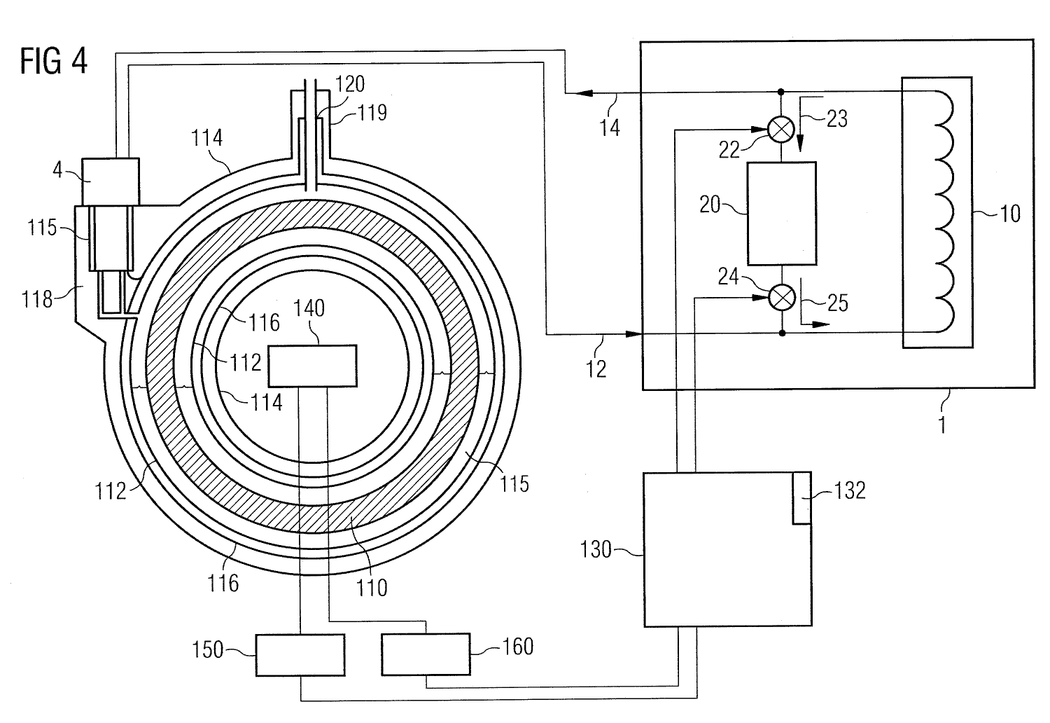

FIG. 4 shows an example embodiment of the present invention, wherein a refrigerator is arranged to cool a superconducting magnet of an MRI system.

It is possible to reduce the power consumption of the gas compressor by at least three alternative methods. Firstly, the operating speed of the compressor may be varied. This option is not preferred in the present invention, since variation in operating speed of the compressor leads to a change in operating speed of the associated refrigerator, which may in turn lead to interference with imaging in an MRI system due to change in the frequency or speed of motion of a magnetic mass within the refrigerator. Another method is to cycle the compressor on and off. This is not preferred as this causes accelerated wear to the compressor and refrigerator, and may also interfere with imaging in an MRI system.

The present invention allows the gas compressor to operate at a reduced input power, and providing a reduced level of refrigeration in an associated refrigeration system, by allowing a reduction in the static charge pressure within a closed gas circuit supplied by the compressor. A typical arrangement comprises a gas compressor connected to a refrigerator by a relatively high pressure output line and a relatively low pressure input line. The gas circuit comprises the supply line, the return line and gas volumes within the compressor and the refrigerator. When the compressor is inoperative, the gas circuit will at least notionally settle to a stable, constant pressure throughout the circuit. This pressure is determined by the mass of gas present in the circuit, the volume of the circuit and the temperature of the gas in the circuit, and is known as the static charge pressure.

The refrigeration power delivered by a cryogenic refrigerator supplied by compressed gas is typically approximately proportional to the input electrical power consumed by the gas compressor. The inventors have found that lowering the static charge pressure in the closed gas circuit supplied by the compressor will reduce the electrical power drawn by the compressor, at the expense of reduced refrigeration power. As described above, the gas compressor and the associated cryogenic refrigerator are typically designed and operated to provide a level of refrigeration sufficient to maintain a superconducting magnet of an MRI system cooled under the most demanding operating conditions—typically encountered during an imaging operation. At other times, such levels of refrigeration are not required. By recognising this, and providing a simple manner in which to control the static charge pressure within the gas circuit, the present invention provides reduced mean power consumption and enhanced operating life of the gas compressor.

The present invention uses variation of the static charge pressure within the gas circuit. It has been found that a reduction in static charge pressure within the gas circuit leads to a reduced operating power consumption in the compressor. The reduction in static charge pressure may be used as an alternative to variation in the speed of operation of the compressor, or these two methods may be used together in some embodiments of the invention. An advantage of varying only the static charge pressure is that the compressor and the refrigerator run at a constant speed, and therefore do not adversely affect the image quality in an MRI system which may otherwise occur due to a varying speed or frequency of a moving magnetic mass within the refrigerator.

FIG. 1 schematically illustrates an arrangement according to the invention, comprising a cryogenic refrigerator 4 and a gas compressor 1, in this case a helium compressor. The compressor 1 includes a compressor capsule 10 which contains an electrically-operated compressor mechanism. A low pressure input line 12 provides gas from the refrigerator 4 to the compressor capsule 10. In this example, the low pressure input line 12 carries helium at a pressure of 4 bar (4×10⁵ Pa). A high pressure output line 14 carries gas from the compressor capsule 10 to the refrigerator 4. In this example, the high pressure output line 14 carries helium at a pressure of 20 bar (20×10⁵ Pa).

With the compressor inoperative, the static charge pressure is 13.5 bar (13.5×10⁵ Pa). With the compressor operative, this static charge pressure represents a mean gas pressure throughout the circuit.

According to an aspect of the present invention, the gas circuit includes a buffer volume 20 connected to the high pressure output line 14 by a controlled inlet valve 22 and connected to the low pressure input line 12 by a controlled outlet valve 24. These valves may be controlled manually, electrically, pneumatically, hydraulically or otherwise. In a preferred embodiment, discussed in more detail below, the inlet and outlet valves 22, 24 are solenoid-operated valves, controlled by a controller of an MRI system.

Gas may be allowed to flow into and out of the buffer volume 20 by appropriate control of inlet valve 22 and outlet valve 24, along paths 23 and 25 respectively. The total volume of the gas path in the compressor 1, the input and output lines 12, 14, the buffer volume 20 and associated paths 23, 25, valves 22, 24 and cryogenic refrigerator 4, supplied by the compressor, may be referred to as a charge volume; the pressure within the input line may be referred to as the input pressure and the pressure within the output line may referred to as the output pressure.

From consideration of the arrangement of FIG. 1, one can define the charge volume as being made up of (i) a high-pressure volume VHP, comprising the volume of the output line 14 and high-pressure volumes within the compressor and the refrigerator; (ii) a low-pressure volume VLP, comprising the volume of the input line 12 and low-pressure volumes within the compressor and the refrigerator; and (iii), according to the present invention, a buffer volume VB, being the volume of buffer volume 20.

Applying the simple Boyle's law formula P1V1=P2V2 to such an arrangement operating under varying pressure conditions,

VHP.OP1+VLP.IP1+VB.BP1=

VHP.OP2+VLP.IP2+VB.BP2=

(VHP+VLP+VB).SCP

### Wherein:

OP1 and IP1 are output and input pressures with a first pressure BP1 of gas within the buffer volume;

OP2 and IP2 are output and input pressures with a second pressure BP2 of gas within the buffer volume; and

SCP is the static charge pressure of gas throughout the charge volume with the compressor inoperative and at least one of the inlet and outlet valves 22, 24 open. As the whole arrangement is sealed, the total mass of gas within the charge volume is constant.

Essentially, the present invention operates as follows. When imaging is taking place, or at other times that full refrigeration power is required, the pressure within buffer volume 20 is reduced to the input pressure, BP1=IP1, reducing the mass of gas within the buffer volume and maximising the mass of gas, and so the static charge pressure, within the gas circuit comprising the high-pressure volume and the low pressure volume. Conversely, when reduced refrigeration power can be tolerated, for example when an associated MRI system is in a standby state, the pressure within buffer volume 20 is increased to the output pressure, BP2=OP2, increasing the mass of gas within the buffer volume and reducing the mass of gas, and so the static charge pressure, within the gas circuit comprising the high-pressure volume and the low pressure volume.

As the total mass of gas remains constant,

at high static charge pressure within the gas circuit:

VHP.OP1+(VLP+VB).IP1=

at low static charge pressure within the gas circuit:

(VHP+VB).OP2+VLP.IP2=

at static charge pressure throughout the charge volume:

(VHP+VLP+VB).SCP

Knowing the high-pressure and low-pressure volumes VHP and VLP, the full-power inlet and outlet pressures IP1 and OP1, and the desired change in static charge pressures of the gas circuit comprising the high-pressure volume, and the low pressure volume, the required volume of buffer volume 20 can be calculated.

A particular embodiment of the present invention will now be described in more detail.

In a normal operating mode, where the compressor is operating at full power, the inlet valve 22 is closed. The volume of the output line is unchanged from the conventional arrangement, the static charge pressure in the gas circuit is at its high value and full refrigeration power is available from refrigerator 4 supplied by the gas compressor. Outlet valve 24 is preferably opened, and the buffer volume 20 will contain gas at the input pressure IP1. Once the pressure in the buffer volume has stabilised, outlet valve 24 may be closed.

According to an aspect of the present invention, when a reduction in cooling performance may be tolerated in order to reduce electrical power consumption, outlet valve 24 is closed and inlet valve 22 is opened between the high pressure output line 14 and the buffer volume 20. Gas at the high output pressure OP1, in this example 20 bar (20×10⁵ Pa), flows into the buffer volume. This increases the mass of gas in the buffer volume, and correspondingly lowers the mass of gas, and so the pressure, in the gas circuit comprising the high-pressure volume and the low pressure volume. In an embodiment of the present invention, the buffer volume 20 is of a size such that the output pressure OP2 is reduced to 18 bar (18×10⁵ Pa) by the opening of inlet valve 22 into the buffer volume 20. This lower output pressure decreases electrical power consumption by the compressor, giving a saving in electrical power consumption, and reducing the mechanical load on the components of the compressor capsule 10.

Inlet valve 22 may then be closed, to trap a volume of gas under output pressure within the buffer volume 20. Alternatively, the inlet valve may be left open, at least until it is required to open the outlet valve to reduce the mass of gas in the buffer volume 20.

The compressor and any associated refrigeration system may be left to operate in this state while an associated MRI system is in a standby state and high-power compression and refrigeration is not required.

Later, high-power compression and refrigeration will be required again. At that time, the mass of gas within the buffer volume 20 must be reduced to its former value, so as to restore the former input and output pressures IP1, OP1. According to an aspect of the present invention, this is achieved by ensuring that the inlet valve 22 is closed and then opening outlet valve 24, discharging the relatively high-pressure gas from the buffer volume 20 into the relatively low-pressure input line 12. The pressure in the buffer volume, in this example, will drop from 18 bar (18×10⁵ Pa) to 4 bar (4×10⁵ Pa), discharging gas into the gas circuit, increasing the input and output pressures IP1, OP1 and so increasing the cooling power delivered by the refrigerator 4. This causes an increase in the electrical power consumed by the compressor. The outlet valve 24 may then be closed, closing the buffer volume to hold a charge of gas at the input pressure. Alternatively, the outlet valve 24 may be left open, at least until it is required to open the inlet valve 22 to increase the mass of gas in the buffer volume 20.

Results of an experiment will now be presented, in which the effects of varying the static charge pressure of the gas circuit on electrical power consumption of a helium gas compressor are measured.

FIG. 2 shows experimental results obtained by operating a helium gas compressor at a range of static charge pressures in the gas circuit in the range 11 bar (11×10⁵ Pa) to 13.5 bar (13.5×10⁵ Pa). A reduction in the static charge pressure of 2.5 bar (from 13.5 bar (13.5×10⁵ Pa) to 11 bar (11×10⁵ Pa)) gives a reduction in electrical power consumption of approximately 1 kVA. This equates to a 15% reduction in electrical power consumption while the compressor is operating with reduced static charge pressure.

Increased electrical power saving could be achieved if the volume of buffer volume 20 was larger, such that the compressor was allowed to run at a yet lower static charge pressure in the gas circuit during low-power operation.

As discussed above, the reduction in the static charge pressure of the gas circuit leads to a reduction in the cooling power of the refrigerator 4. FIG. 3 shows experimental results comparing the reduction in recondensing margin of a refrigerator cooling an MRI magnet and supplied by a compressor, according to the present invention, with varying static charge pressure of the gas circuit for the helium compressor used in the experiment of FIG. 2, over the same range of static charge pressures.

The recondensing margin represents the cooling power delivered by a refrigeration system associated with the helium compressor, in excess of the cooling power required to just recondense helium vapour being boiled off by the cooled magnet operating with liquid helium cooling. Typically, only 100 mW recondensing margin is required. However, conventionally, the refrigerator is operated so as to provide at least 100 mW recondensing margin when an associated MRI system is performing an imaging sequence, and the cooled magnet is generating a maximum amount of heat, and is operated continuously at this power, providing an unnecessarily large recondensing margin at other times.

As illustrated in FIG. 3, with a static charge pressure in the gas circuit of 13.5 bar (13.5×10⁵ Pa), a recondensing margin of about 725 mW is achieved when the MRI magnet system is in a standby, non-imaging state. As also illustrated in FIG. 3, a reduction of 2.5 bar (2.5×10⁵ Pa) in static charge pressure results in a drop of some 130 mW recondensing margin, but still provides a plentiful recondensing margin of some 590 mW.

It may be expected that a further significant reduction of static charge pressure in the gas circuit, such as a further 2.5 bar (2.5×10⁵ Pa) would result in further reductions in electrical power consumption while still maintaining a recondensing margin of well over 100 mW when the MRI magnet system is in a standby, non-imaging state.

The compressor 1 comprises compressor capsule 10 and the required electrical connections, and also includes the buffer volume 20 and inlet and outlet Valves 22, 24. The present invention accordingly delivers a solution which is able to achieve input electrical power savings when an associated MRI system is in a power saving mode, for example when the system is in stand-by, by tolerating reduced refrigeration power at such times.

FIG. 4 shows an example embodiment of the present invention, wherein the refrigerator 4 is arranged to cool a superconducting magnet 110 of an MRI system. Cooled superconducting magnet 10 is provided within a cryogen vessel 112, itself retained within an outer vacuum chamber (OVC) 114. The magnet is partially immersed in a liquid cryogen 115, for example liquid helium at a temperature of about 4.2K. One or more thermal radiation shields 116 are typically provided in the vacuum space between the cryogen vessel 112 and the outer vacuum chamber 114. Refrigerator 4 is mounted in a refrigerator sock 115 located in a turret 118 provided for the purpose, towards the side of the cryostat. Alternatively, refrigerator 4 may be located within access turret 119, which retains access neck (vent tube) 120 mounted at the top of the cryostat. The refrigerator 4 typically has two or more refrigeration stages. The first stage, in a helium-cooled system, is typically thermally linked, as shown, to thermal radiation shield 116, and cools the shield to a temperature in the range 50-100K. The second stage typically cools cryogen gas within the cryogen vessel 112 to a temperature in the region 4-10K, in some arrangements by recondensing it into liquid 115. The refrigerator 4 is connected to output line 14 and input line 12, and forms part of a gas circuit as described above. A controller 130, such as a computer-based controller, is provided to control operation of the MRI system including the magnet arrangement shown. The controller is, in this example, connected to control the inlet valve 22 and outlet valve 24. The controller will be arranged and connected to perform other control operations as well, but they are not relevant to the present invention. The MRI system also comprises the following features, which are only schematically represented in FIG. 4. Gradient and RF coils 140 are provided within the bore of the superconducting magnet. The gradient coils generate time-varying magnetic fields which induce magnetic resonance in a subject to be imaged. The RF coil, alternatively known as the body coil, picks up signals representing the magnetic resonance in the subject. A gradient power supply 150 provides power to the gradient coils. Image processing equipment 160 receives the signals from the RF coil and produces an image from them. The gradient power supply 150 and the image processing equipment 160 are controlled by the controller 130. An operator may operate controls 132 of the controller to command the MRI system to enter a non-imaging, standby state, or to leave the non-imaging, standby state typically when imaging is required.

In the arrangement of FIG. 4, an MRI system comprises superconducting magnet 110 cooled by a liquid cryogen 115 which is cooled by cryogenic refrigerator 4 (for example, either a Gifford McMahon or a Pulse Tube type) which is supplied with compressed gas by compressor 1, according to the present invention. The liquid cryogen 115 may be helium, or may be another cryogen such as nitrogen, largely depending on the superconducting material used in the magnet 110. As is conventional, operation of the MRI system is controlled by a computer based controller 130. The inlet and outlet valves 22, 24 may be solenoid operated valves, electrically controlled by the controller 130. In such an arrangement, the inlet valve 22 may be opened, with outlet valve 24 closed, reducing the static charge pressure of the gas circuit, when the MRI system enters a non-imaging standby state. The outlet valve 24 may be opened, with inlet valve 22 closed, increasing the static charge pressure of the gas circuit, when the MRI system leaves the non-imaging, standby state.

While the present invention has been described by reference to certain embodiments, it will be appreciated by those skilled in the art that numerous variations and modifications of the present invention are contemplated and covered by the scope of the appended claims. For example, while the invention has been particularly described with reference to a compressor for supplying compressed helium to a refrigerator for cooling superconducting coils of a magnet of an MRI system, the present invention may be applied to any gas compressor, whether helium or otherwise, and for any application.

While the present invention has been particularly described with reference to electrically powered gas compressors, it will also be apparent to those skilled in the art that non-electrically powered compressors may be used, such as those operated by stored mechanical energy, combustion engines, driven by a turbine, or other energy sources. In the case of these alternatively-powered compressors, the reduction in power consumption may still be a valuable benefit of the present invention. The reduction in mechanical wear of the compressor will be a welcome benefit regardless of the manner in which the compressor is driven.

1. An arrangement for cooling equipment comprising a cryogenic refrigerator arranged to receive compressed gas from a compressor, said compressor including:
a compressor mechanism;
an input line for providing gas to the compressor mechanism; and
an output line for providing compressed gas from the compressor mechanism,
the compressor further including a buffer volume connected to the output line by a controlled inlet valve and connected to the input line by a controlled outlet valve,
said compressor mechanism, said refrigerator, said input line, said output line, said buffer volume and said inlet and outlet valves forming a closed gas circuit,
such that, in use, the refrigerator may be operated at a first refrigerating power in response to the buffer volume containing gas at the same pressure as the output line, and the refrigerator may be operated at a second refrigerating power, greater than the first, in response to the buffer volume containing gas at the same pressure as the input line, the pressure within the buffer volume being adjustable in response to operation of the inlet valve and the outlet valve.

2. An arrangement for cooling equipment according to claim 1 wherein the cryogenic refrigerator is selected from the group comprising: a Gifford-McMahon type refrigerator; and a pulse tube refrigerator.

3. A magnetic resonance imaging (MRI) system comprising superconducting coils arranged to generate a magnetic field and housed within a cryostat vessel containing liquid cryogen arranged to be cooled by an arrangement according to claim 1.

4. A magnetic resonance imaging (MRI) system according to claim 3 wherein the liquid cryogen is liquid helium.

5. A magnetic resonance imaging (MRI) system according to claim 3, further comprising a controller for controlling the MRI system, characterised in that the controller is arranged to control the inlet and outlet valves.

6. A method of operating a cryogenic refrigerator arranged to receive compressed gas from a compressor comprising the steps of:
providing a compressor mechanism, an input line providing gas from the refrigerator to the compressor mechanism; and an output line providing compressed gas from the compressor mechanism to the refrigerator;
providing a buffer volume connected to the output line by a controlled inlet valve and connected to the input line by a controlled outlet valve,
said compressor mechanism, said refrigerator, said input line, said output line, said buffer volume and said inlet and outlet valves forming a closed gas circuit;
with the compressor mechanism operating, closing the outlet valve and opening the inlet valves whereby the pressure within buffer volume is raised to a pressure (OP2) equal to the pressure in the output line;
operating the refrigerator at a first refrigerating power;
with the compressor mechanism operating, closing the inlet valve and opening the outlet valves whereby the pressure within buffer volume is reduced to a pressure (IP1) equal to the pressure in the input line; and
operating the refrigerator at a second refrigerating power, greater than the first refrigerating power, in response to the increased mass of gas flowing through the compressor mechanism, input line, output line and refrigerator due to the reduced mass of gas held within the buffer volume.

7. A method according to claim 6 for cooling a superconducting magnet in an MRI (Magnetic Resonance Imaging) system, wherein:
the inlet valve is opened, with the outlet valve closed and the refrigerator operated at the first refrigerating power when the MRI system enters a non-imaging standby state; and
the outlet valve is opened, with the inlet valve closed and the refrigerator operated at the first refrigerating power when the MRI system leaves the non-imaging, standby state.

8. A method according to claim 7 wherein the compressor is operated at a same speed when supplying gas to the refrigerator operating at the first refrigerating power as when supplying gas to the refrigerator operating at the second refrigerating power.

9. A method according to claim 6, comprising the steps of:
supplying a first input power to the compressor mechanism when the refrigerator is operating at the first refrigeration power; and
supplying a second input power, greater than said first input power, to the compressor mechanism when the refrigerator is operating at the second refrigeration power.

10. A method according to claim 9 wherein the first input power and the second input power are electrical powers.

11.-12. (canceled)
